(19) United States
(12) Patent Application Publication
(10) Pub. No.: US 2003/0025148 A1
(43) Pub. Date: Feb. 6, 2003

(54) Structure of a flash memory

(76) Inventors: Jung-Yu Hsieh, Taipei Hsien (TW); Chin-Hsiang Lin, Nantou Hsien (TW)

Correspondence Address: J. C. Patents, Inc., Suite 250, 4 Venture, Irvine, CA, 92618, US

(21) Appl. No.: 09/990,862

(22) Filed: Nov. 13, 2001

(30) Foreign Application Priority Data
May 4, 2001 (TW) 90110698

(51) Int. Cl. H01L 29/788

(52) U.S. Cl. 257/315

(57) ABSTRACT

A structure of a flash memory is provided. The flash memory has a charge trapping layer, a gate and a source/drain region, wherein the charge trapping layer is formed by stacking in sequence a first oxide layer, a dielectric layer of high dielectric constant material and a second oxide layer. The gate is arranged on the charge trapping layer, and the source/drain region is arranged at the two lateral sides of the substrate.

### CROSS-REFERENCE TO RELATED APPLICATION

This application claims the priority benefit of Taiwan application serial no. 90110698, filed May 4, 2001.

### BACKGROUND OF THE INVENTION

1. Field of the Invention

The present invention relates to structure of a memory, and in particular, a structure of a flash memory.

2. Description of the Prior Art

In recent years, as a result of high demand of portable electronic appliances, there has been a great increase in demand for flash memories. The manufacturing technology of a flash memory has gradually matured and developed. Thus, the cost of production has been lowered and in turn, purchasing activities will be stimulated and new applications of a flash memory will be developed. The recently developed electrically erasable and program ROM has a faster storage speed. Therefore, it has been widely used in film for digital cameras, memory for PDA, MP3 players, electronic answering devices, programmable ICs, etc, which are the market applications of a flash memory.

A conventional flash memory employs doped polycrystalline silicon to manufacture a floating gate and a control gate. When the memory proceeds to program, appropriate program voltages are respectively added to the source region, the drain region and the control gate. Electrons flow from the source region to the drain via channel. In this process, some of the electrons will pass through the tunneling oxide layer beneath the polycrystalline silicon floating gate layer and enter into and distribute evenly throughout the entire polycrystalline floating gate layer. The phenomenon of electrons passing through the oxide layer into the polycrystalline floating gate is known as the tunneling effect. This tunneling effect can be further classified into two different situations, Channel Hot-Electron Injection and Fowler-Nordheim Tunneling (F-N Tunneling). Generally, a flash memory is programmed by way of Channel Hot-Electron Injection and passes though the side of the source, or the channel region is erased by F-N Tunneling. However, if a weak point exists at the tunneling oxide layer beneath the polycrystalline silicon floating gate, current leakage of the memory element can easily occurr, which affects the reliability of the memory element.

In order to solve the problem of current leakage within the flash memory element, a recent method that has been developed is the formation of a charge trapping layer on the substrate. The material for the charge trapping layer is a stacked structure of SiO2/Si3N4/SiO2 (Oxide-Nitride-Oxide) (abbreviated as ONO) complex layers, and source region and drain regions are formed subsequently on the substrate of the two lateral sides of the ONO layer.

The silicon nitride layer of the ONO charge trapping layer has a charge gripping effect, so the electrons injected to the ONO layer will not evenly distribute on the entire silicon nitride but are concentrated on only a portion of the silicon nitride by way of Gaussian distribution. Thus, the sensitivity on the weak point of the oxide layer is low and current leakage will not occur easily. As silicon nitride layer of the charge trapping layer is the essentially layer to grip electrons, this memory cell is known as Silicon Nitride Read Only Memory (NROM).

Additionally, the advantage of the ONO charge trapping layer is that the electrons will only approach the tunnel at the top section of the source or drain for partial storage during element programming. Thus, in the course of the program, the source/drain region and the gate can be respectively applied with voltage, and when approaching the silicon nitride layer at the other end of the source/drain region, Gaussian distributed electrons are generated. Thus, by changing the application of the voltage at the gate and the two lateral sides of the source/drain region, a single ONO charge trapping layer can have two electrons with Gaussian distribution, a single electron with Gaussian distribution, or no electrons. Thus, if silicon nitride is used as a material for a flash memory of the charge trapping layer, four kinds of states can be written to a single memory cell, thus forming a 1 cell 2 bit flash memory.

However, as the number of programming/erasing operations of the memory increases, damage on the silicon oxide of the ONO will become more serious, leading to a change in threshold voltage (denoted by Vₜₕ). As the change of threshold voltage increases, the leakage of electrons is increased, and the data retention of the memory is reduced. Thus, minimizing the variation of threshold voltage is an imperative issue.

### SUMMARY OF THE INVENTION

Accordingly, it is an object of the present invention to provide a structure of a flash memory, which reduces the amount of variation of the threshold voltage and enhances data retention of the flash memory.

It is another object of the present invention is to provide a structure of a flash memory comprising an electron trapping layer, a gate and a source/drain region, wherein the electron trapping layer is formed by stacking in sequence a first oxide layer and a dielectric layer with a high dielectric constant. The gate is arranged on the electron trapping layer, and the source/drain region is arranged on the substrate of the two lateral sides of the electron trapping layer. In addition, the band gap of the material used for the high dielectric constant dielectric layer determines whether or not a second oxide layer should be provided on the high dielectric constant dielectric layer. The second oxide layer is not needed if the band gap of the high dielectric constant dielectric layer is closer to or greater than that of silicon oxide. On the other hand, a second oxide layer is needed if the band gap is smaller than that of silicon oxide.

In the present invention, a material with a high dielectric constant refers to a material with a dielectric constant higher than that of Si₃N₄/SiO₂ (also known as NO), so such a term in the present invention is not a formal term. The band gap refers to the gap between two tolerable electron energy bands of metal and semiconductor.

The advantage of the present invention is that a high dielectric constant material is used as the main material for the dielectric layer. Thus, the amount of variation of the threshold voltage is greatly reduced, and data retention of the flash memory is enhanced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a preferred embodiment of the flash memory of the present invention.

### DETAILED DESCRIPTION OF THE PRESENT INVENTION

Reference will now be made in detail to the present preferred embodiments of the invention, examples of which are illustrated in the accompanying drawings. Wherever possible, the same reference numbers are used in the drawings and the description to refer to the same or like parts.

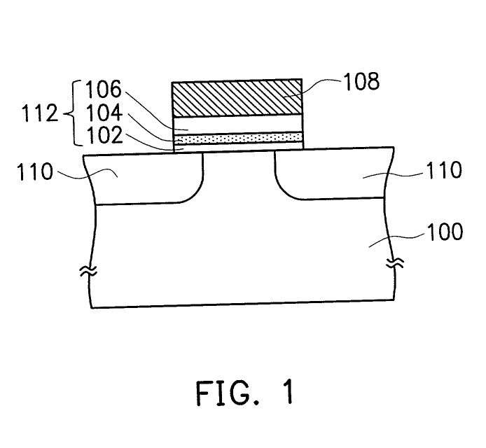

The present invention provides a structure of a flash memory which reduces the variation of the threshold voltage to a minimum. FIG. 1 is a cross-sectional view of a preferred embodiment of the flash memory of the present invention.

As shown in FIG. 1, the flash memory comprises an electron trapping layer 112, a gate 108 and a source/drain region 110. The gate 108 is located on the electron trapping layer 112, and the source/drain region 110 is positioned at the two lateral sides of a substrate 100. The electron trapping layer 112 is formed by stacking a first oxide layer 102 and a dielectric layer 104. The dielectric layer 104 is made from a material with a high dielectric constant.

In accordance with the present invention, the material of the dielectric layer 104 of the electron trapping layer 112 requires a high dielectric constant (ε). The reason for using a material with a high dielectric constant is shown by the relationship of the threshold voltage being varied with respect to time (denoted by ΔVₜₕ(t)) and the dielectric constant, as follows:

$$Δ {V}_{th} ( t ) = - 2.3 \frac{\overline{{t}_{ONO}}}{{ϵ}_{ONO}} \times \frac{q \overline{n} {N}_{DX}}{2 \sqrt{2 {mE}_{to}}} \times log t$$

where

ε_{ONO} is the dielectric constant of the ONO layer;

Eₜₒ is the Oxide Trap Energy; and

qN_{DX} is the Trap Charge Density.

Accordingly, the dielectric constant of the dielectric layer 104 for the electron trapping layer 112 has to be upgraded in order to reduce the amount of variation ΔVₜₕ(t) of the threshold voltage. The flash memory structure of the present invention employs a material having a high dielectric constant when manufacturing the electron trapping layer 112 in order to reduce the amount of variation of the threshold voltage. Thus, the data retention of the flash memory is enhanced.

The first oxide layer 102 of the electron trapping layer 112 is used to enhance adsorption force between the substrate 100 and the high dielectric constant dielectric layer 104 and to avoid the formation of a defect. Additionally, as shown in FIG. 1, the electron trapping layer 112 further comprises a second oxide layer 106 on the dielectric layer 104 made from a high dielectric constant material, wherein the second oxide layer 106 is used to enhance the adsorption force between the high dielectric constant dielectric layer 104 and the gate 108 formed subsequently thereon and to avoid the formation of a defect.

In the present invention, a material having high dielectric constant refers to a material with a dielectric constant higher than that of Si₃N₄/SiO₂ (also known as NO). The materials for the high dielectric constant layer 104 are, for example, Al₂O₃, Y₂O₃, ZrSiₓO_{y}, HfSiₓO_{y}, La₂O₃, ZrO₂, HfO₂, Ta₂O₅, Pr₂O₃ and TiO₂.

The following table 1 shows the dielectric constants of the above-mentioned high-dielectric constant materials, also including Si₃N₄/SiO₂, SiO₂ and Si₃N₄.

TABLE 1

| Materials | Dielectric Constant |
|---|---|
| SiO₂ | 2-9 |
| Si₃N₄ | 7.5 |
| NO (Si₃N₄/SiO₂) | 7-8 |
| Al₂O₃ | 10 |
| Y₂O₃ | 12-14 |
| ZrSiₓO_{y} | 12-22 |
| HfSiₓO_{y} | 15-25 |
| La₂O₃ | 20 |
| ZrO₂ | 22 |
| HfO₂ | 25 |
| Ta₂O₅ | 26 |
| Pr₂O₃ | 31 |
| TiO₂ | 80 |

As shown in Table 1, the dielectric constant of the high dielectric constant material of the present invention is higher than 8, which is the dielectric constant for Si₃N₄/SiO₂. In addition, the high dielectric constant dielectric layer 104 of the present preferred embodiment can be, for example, a mixture of the above-mentioned high dielectric constant dielectric materials or a stack layer of the above-mentioned high dielectric constant materials. Due to the fact that high dielectric constant material is used as the material for the dielectric layer, the variation of the threshold voltage is greatly reduced, and in turn, the data retention of the flash memory is enhanced.

In addition, the band gap of the material of the high dielectric constant dielectric layer 104 determines whether or not a second oxide layer 106 should be provided to the high dielectric constant layer 104. The second oxide layer 106 is not needed if the band gap of the dielectric layer 104 is closer to or greater than that of silicon oxide. On the other hand, the second oxide layer 106 is needed if the band gap is smaller than that of silicon oxide. Table 2 shows the band gap of the materials used for the dielectric layer 104 in the preferred embodiment of the present invention. The band gaps of SiO₂ and Si₃N₄ are also shown in Table 2.

TABLE 2

| Materials | Band Gap (eV) |
|---|---|
| SiO₂ | 9 |
| Si₃N₄ | 5.3 |
| Al₂O₃ | 8.0 |
| Y₂O₃ | 5.6 |
| ZrSiₓO_{y} | 6.5 |
| HfSiₓO_{y} | 6.5 |
| La₂O₃ | 4 |
| ZrO₂ | 7.8 |
| HfO₂ | 6 |
| Ta₂O₅ | 4.4 |
| Pr₂O₃ | — |
| TiO₂ | 2.3 |

If the band gap of the dielectric layer 104 is close to or larger than that of the conventional SiO₂ layer, then the dielectric layer 104 can be substituted for the conventional oxide layer formed on the dielectric layer and can have identical effects.

The present invention is characterized in that a high dielectric constant material is used as a main material for the dielectric layer. Accordingly, the variation of the threshold voltage is greatly reduced, and in turn, the data retention of the flash memory is enhanced. Thus, the effectiveness of the flash memory is greatly improved, thereby increasing efficiency and speed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of a flash memory comprising:
a first oxide layer positioned on a substrate;
a dielectric layer having a high dielectric constant positioned on the first oxide layer;
a second oxide layer positioned on the dielectric layer having the high dielectric constant, wherein the first oxide layer, the dielectric layer having the high dielectric constant and the second oxide layer together form a charge trapping layer; and
a gate located on the second oxide layer of the charge trapping layer; and
a source/drain region located at two lateral sides of the substrate.

2. The structure of claim 1, wherein a band gap of the dielectric layer having the high dielectric constant is smaller than that of silicon oxide (SiO₂).

3. The structure of claim 1, wherein the dielectric constant of the dielectric layer having the high dielectric constant is greater than 8.

4. The structure of claim 1, wherein the material of the dielectric layer having the high dielectric constant is selected from a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

5. The structure of claim 1, wherein the material of the dielectric layer having the high dielectric constant is a mixture of materials selected from the a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

6. The structure of claim 1, wherein the dielectric layer having the high dielectric constant is a stacked layer having layers made of materials selected from a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

7. A structure of a flash memory comprising:
a first oxide layer positioned on a substrate;
a dielectric layer having a high dielectric constant positioned on the first oxide layer, wherein the dielectric layer and the first oxide layer together form a charge trapping layer; and
a gate positioned on the dielectric layer having the high dielectric constant; and
a source/drain region positioned at two lateral sides of the substrate.

8. The structure of claim 7, wherein a band gap of the dielectric layer having the high dielectric constant is larger than that of silicon oxide (SiO₂).

9. The structure of claim 7, wherein the band gap of the dielectric layer having the high dielectric constant is equal to that of silicon oxide (SiO₂).

10. The structure of claim 7, wherein the material of the dielectric layer having the high dielectric constant is selected from a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

11. The structure of claim 7, wherein the material of the dielectric layer having the high dielectric constant is a mixture of materials selected from a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

12. The structure of claim 7, wherein the dielectric layer having the high dielectric constant is a stacked layer having layers made of materials selected from a group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.
